(19) United States
(12) Patent Application Publication
(10) Pub. No.: US 2016/0126383 A1
(43) Pub. Date: May 5, 2016

(54) PHOTOVOLTAIC MODULE WITH IMPROVED BONDING

(71) Applicant: Eduardo Hipolito Gacho, Paranaque (PH)

(72) Inventor: Eduardo Hipolito Gacho, Paranaque (PH)

(21) Appl. No.: 14/924,048

(22) Filed: Oct. 27, 2015

Related U.S. Application Data
(60) Provisional application No. 62/073,747, filed on Oct. 31, 2014.

(51) Int. Cl. H01L 31/048; H02S 30/10

(52) U.S. Cl. CPC H01L 31/048; H02S 30/10

(57) ABSTRACT

A solar module can include a laminate having an edge and a receptacle of a frame portion connected to the edge of the laminate. In an embodiment, an adhesive can be formed in the receptacle of the frame portion. In one embodiment, the adhesive can bond the laminate to the frame portion. In an embodiment, the adhesive can be a partially cured adhesive, where the partially cured adhesive can be heated to form a cured adhesive and to bond the laminate to a frame. In an embodiment, the adhesive can be an epoxy, B-stage epoxy or a silicone sealant.

### CROSS-REFERENCE TO RELATED APPLICATIONS

This application claims the benefit of U.S. Provisional Application No. 62/073,747, filed on Oct. 31, 2014, the entire contents of which are hereby incorporated by reference herein.

### BACKGROUND

Photovoltaic (PV) cells, commonly known as solar cells, are devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collect from all of the PV cells can be combined in series and parallel arrangements to provide power with a certain voltage and current.

PV modules can include laminates having the array of PV cells and frames for maintaining the structural integrity of the PV module. Proper bonding and alignment between frame and laminate can prevent structural defects and maintain aesthetic value of the PV module.

### BRIEF DESCRIPTION OF THE DRAWINGS

FIG. 1 illustrates a flow chart representation of an example method for manufacturing of a PV module, according to some embodiments.

FIG. 2 illustrates a cross-sectional view of a frame portion, according to some embodiments.

FIG. 3 illustrates a profile view of the frame portion of FIG. 2, according to some embodiments.

FIG. 4 illustrates a cross-sectional view of placing a laminate in a receptacle of the frame portion of FIGS. 1 and 2, according to some embodiments.

FIG. 5 illustrates a cross-sectional view of pressing and curing a partially cured adhesive to fit and bond a laminate to the frame portion of FIGS. 1 and 2, according to some embodiments.

FIG. 6 illustrates a profile view of pressing first, second, third and fourth frame portions to a laminate to form a PV module, according to some embodiments.

FIG. 7 illustrates an example PV module, according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” frame portion does not necessarily imply that this frame portion is the first frame portion in a sequence; instead the term “first” is used to differentiate this frame portion from another frame portion (e.g., a “second” frame portion). A frame portion can be a part of a frame, e.g., a first frame portion can be a side of a four sided frame.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

This specification first describes an example method of forming a PV module. This specification also provides a more detailed description of the frame portion, partially cured adhesive and steps in a method to bond the laminate to the frame portion. As used throughout the specification, a PV module can be referred to as a solar module. Also, a laminate can be an array of solar cells encapsulated in an encapsulant. Various examples are provided throughout.

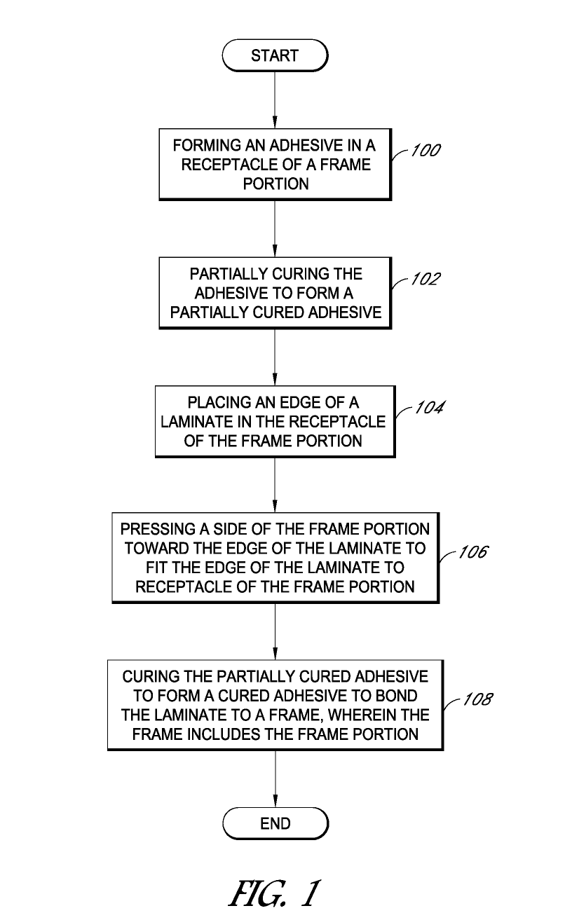

Turning now to FIG. 1, a flow chart illustrating a method for forming a solar module is shown, according to some embodiments. In various embodiments, the method of FIG. 1 can include additional (or fewer) blocks than illustrated. For example, in some embodiments, a frame portion can include a partially cured adhesive already formed in a receptacle of the frame portion, therefore blocks 100 and 102 need not be performed in such embodiments.

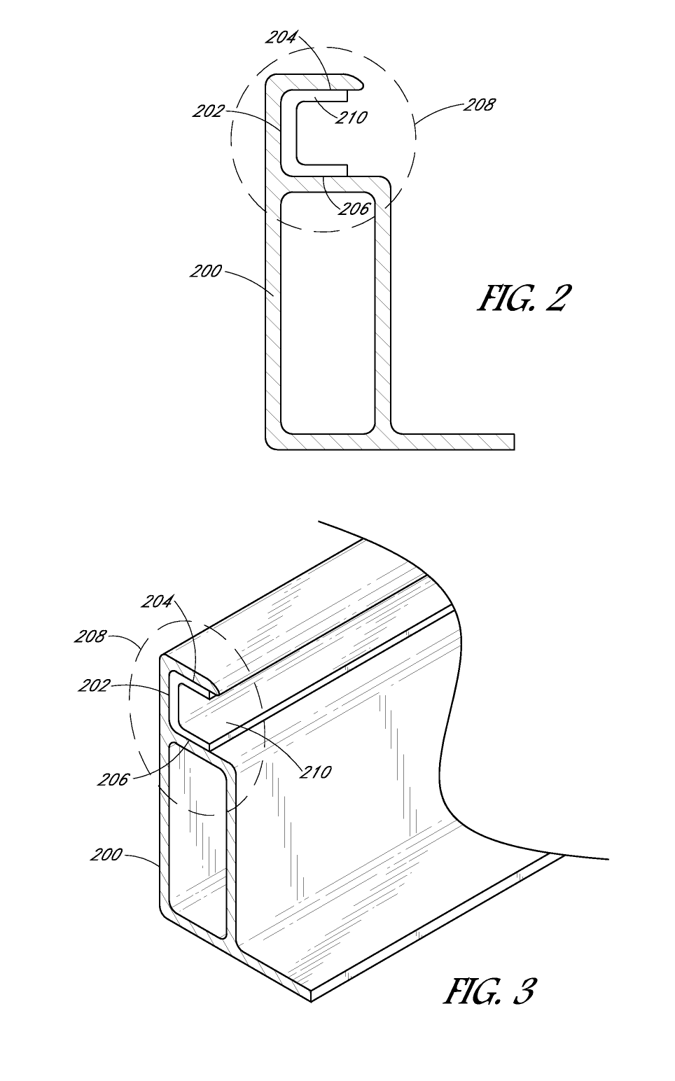

At 100, an adhesive can be formed in a receptacle of the frame portion. In an embodiment, the adhesive can be an epoxy based adhesive or an epoxy based tape. In an embodiment, the adhesive can be a silicone sealant. In some embodiments, the adhesive can be applied or deposited. In an embodiment, the receptacle can be an opening in the frame portion. In some embodiments, the receptacle can be referred to as a channel or canal. For example, the receptacle can have three sides and the adhesive can be formed on one or more of the three sides as shown in 208 FIG. 2.

At 102, the adhesive can be partially cured to from a partially cured adhesive. In an embodiment, the adhesive can be heated to form a partially cured adhesive. In some embodiments, the heating is only sufficient to partially cure the adhesive, where a catalyst of the adhesive controls the curing process. A subsequent curing and/or heating step can be performed to fully cure the partially cured adhesive, for example, after the laminate is positioned in the receptacle as described in more detail below.

In some embodiments, the adhesive can be heated with an oven, blow drying or any other type of heating process. In an embodiment, the partially cured adhesive can be a partially cured epoxy. In an example, the partially cured adhesive can be a B-stage epoxy. In an embodiment, using partially cured epoxies can have advantages over using uncured epoxies (e.g. A-stage epoxies), such as reducing overall cure time required for performing a bonding process.

In some embodiments, the partially cured adhesive can be pre-formed in the receptacle of the frame portion. In one embodiment, the partially cured adhesive can be an adhesive film or tape. In an embodiment, the tape can be an epoxy based tape. In some embodiments, the partially cured adhesive can be rolled into the receptacle. In one example, the adhesive film can be rolled into the receptacle. In an embodiment, providing a frame portion with the partially cured adhesive pre-formed can reduce the number of operation steps in a framing or manufacturing process, with blocks 100 and 102 not needing to be performed.

At 104, an edge of the laminate can be placed in the receptacle of the frame portion. In an embodiment, the edge of the laminate can contact the partially cured adhesive formed in the receptacle of the frame portion. In an embodiment, a first edge of the laminate can be placed in a receptacle of a first frame portion. In some embodiments, other edges of the laminate can be placed in a receptacle of other frame portions, respectively. For example, second, third, and/or fourth edges of the laminate can be placed in receptacles of the second, third, and/or fourth frame portions, respectively.

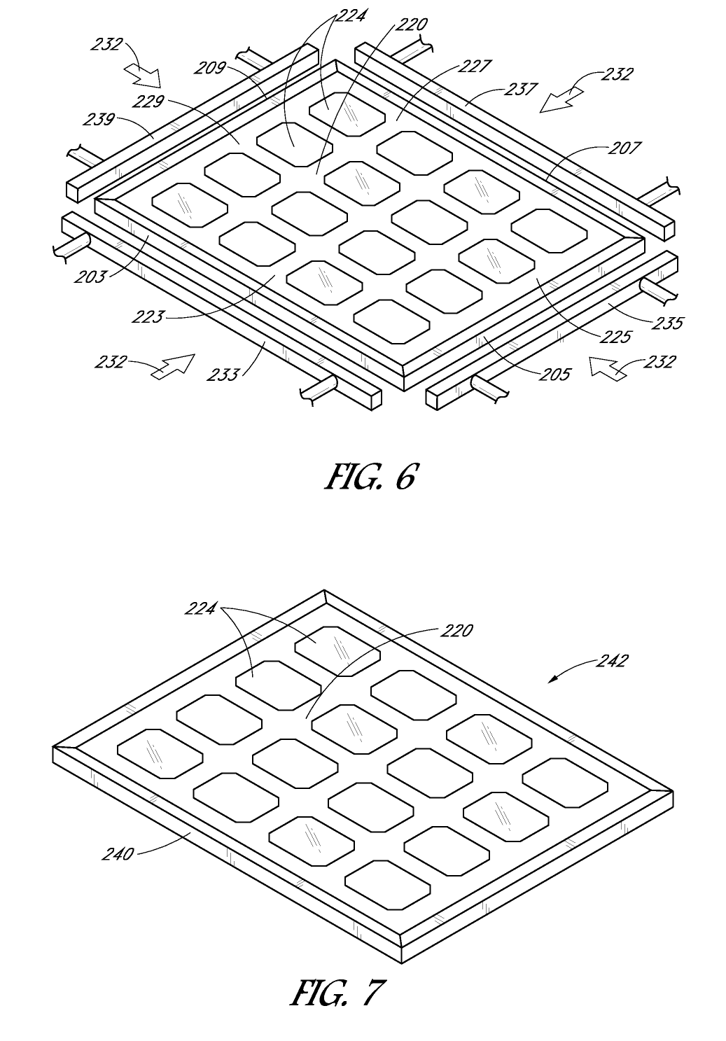

At 106, a side of the frame portion can be pressed toward the edge of the laminate. In an embodiment, the pressing can be performed to fit the edge of the laminate to the receptacle of the frame portion. In an embodiment, a side of a first frame portion can be pressed toward a first edge of a laminate. In some embodiments, sides of other frame portions can be pressed toward other edges of the laminate, respectively. For example, sides of second, third, and/or fourth frame portions can be pressed toward the second, third, and/or fourth edges of the laminate, respectively. In an embodiment, pressing a side of the frame portion can in turn press a side of the receptacle to contact the edge of the laminate. In an example, the pressing can be performed to ensure the frame portions form a square or rectangular shape, as shown in FIGS. 6 and 7. In some embodiments, one or more of the sides of all four frame portions can be simultaneously pressed toward the four edges of the laminate in a single process (e.g., in a single step), respectively.

At 108, the partially cured adhesive can be cured, with the laminate in place in the receptacle, to form a cured adhesive to bond the laminate to a frame. In an embodiment, the curing can include heating and/or ultraviolet (UV) curing. As noted above, the frame can include any number of frame portions, e.g., a first, second, third, fourth frame portion, etc. In an embodiment, the partially cured adhesive can be cured to form a cured adhesive to bond an edge of the laminate to a frame portion. In one embodiment, the partially cured adhesive can reflow during curing and surround an edge of the laminate after the curing process as shown in FIG. 5. For example, reflowing the partially cured adhesive can maximize the surface area (e.g., totally surround) the edge of the laminate. In an embodiment, the reflow of the partially cured adhesive can fill any air gaps at the edge of the laminate and/or between the edge of the laminate and the receptacle of the frame portion. In one embodiment, the reflow of the partially cured adhesive can tightly seal the edge of the laminate, where the partially cured adhesive can prevent against moisture ingression at the edge of the laminate.

FIGS. 2 and 3 illustrate an example frame portion, according to some embodiments. FIG. 2 shows a cross-sectional view of the frame portion 200 and FIG. 3 shows a profile view of the frame portion 200. In an embodiment, the frame portion 200 can include a receptacle 208. In some embodiments, the receptacle 208 can have middle 202, top 204 and bottom 206 sides. In an embodiment, a partially cured adhesive can be formed inside the receptacle 208. In an embodiment, the partially adhesive can be formed using the method of FIG. 1. In an example, the partially cured adhesive can be formed on one side, e.g. the middle side 202 or the bottom side 206, of the frame portion 200. In another example, the partially cured adhesive 210 can be formed on one or more than one side, for example, on the three sides 202, 204, 206 of the frame portion 200 as shown in FIGS. 2 and 3.

In one embodiment, the partially cured adhesive 210 can be an epoxy. In an example, the partially cured adhesive 210 can be a B-type epoxy or a silicone sealant. In some embodiments, the adhesive can be an adhesive film or tape. In one embodiment, the adhesive film or tape can be rolled in the receptacle 208.

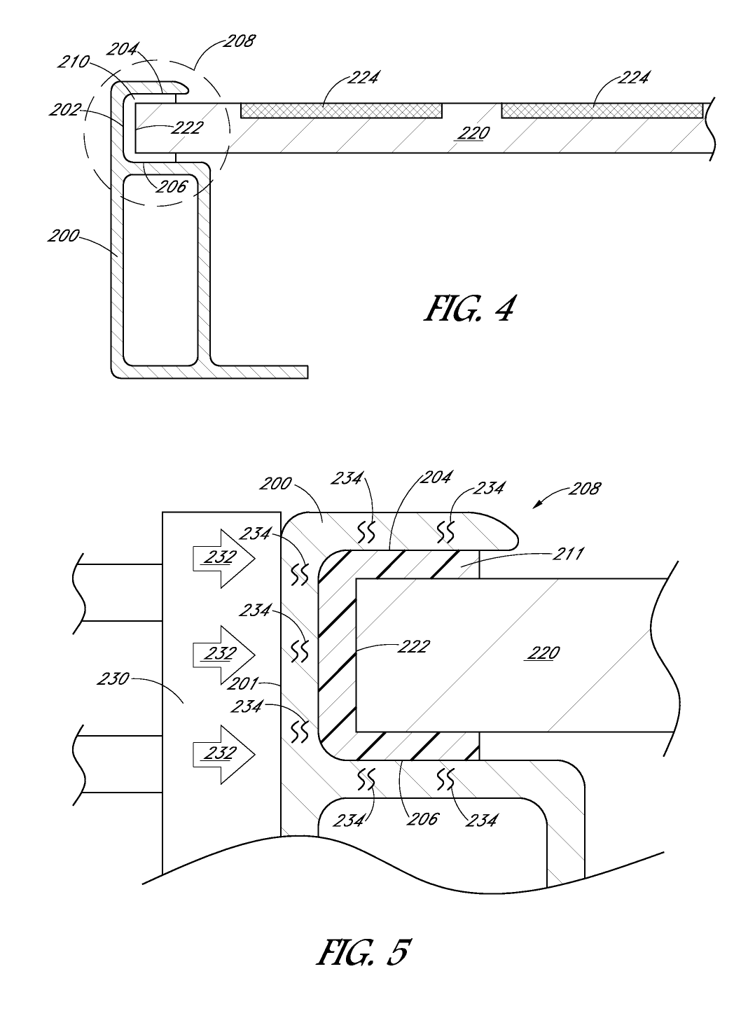

With reference to FIG. 4, placing an edge of a laminate in the receptacle of the frame portion is shown, according to some embodiments. In an embodiment, the laminate 220 can include solar cells 224. In an example, the edge of the laminate 222 can contact the partially cured adhesive 210. In one example, as shown in FIG. 4, the partially cured adhesive 210 can surround the edge 222 of the laminate 220.

FIG. 5 illustrates pressing a side of the frame portion toward the edge of the laminate, according to some embodiments. In an embodiment, the side 201 of the frame portion 200 can be pressed toward 232 the edge 222 of the laminate 220 to fit the edge 222 of the laminate 220 to the receptacle 208 of the frame portion 200.

In an embodiment, the partially cured adhesive 210 can be cured 234 to form a cured adhesive 211. In an embodiment, the curing 234 can include heating the partially cured adhesive to form a cured adhesive 211. In one embodiment, the curing 234 bonds the frame portion 200 to the laminate 220. In an embodiment, the curing 234 can be performed before the pressing 232. In some embodiments, a heat plate can be used to heat the partially cured adhesive to form a cured adhesive 211. In one embodiment, as shown in FIG. 5, a heat plate 230 can be used to both press 232 the side 201 of the frame portion 200 toward the edge 222 of the laminate 220 and heat 234 the partially cured adhesive to form a cured adhesive 211 and bond the frame portion 200 to the laminate 220.

With reference to FIG. 6, pressing first, second, third, and fourth frame portions to edges of a laminate to form a solar module is shown, according to some embodiments. In an example, a laminate 220 with first 223, second 225, third 227 and fourth 229 edges can be provided. In an embodiment, first 233, second 235, third 237 and fourth 239 metal plates can be used to press 232 first 203, second 205, third 207 and fourth 209 frame portions to the edges 223, 225, 227, 229 of the laminate 220, respectively. In one embodiment, the pressing 232 can fit the first 223, second 225, third 227 and fourth 229 edges of the laminate 220 to the first 203, second 205, third 207, fourth 209 frame portions. In an embodiment, a frame can be formed after pressing the frame portions 203, 205, 207, 209 to the edges 223, 225, 227, 229 of the laminate 220, where the frame includes the frame portions 203, 205, 207, 209. In some embodiments, the metal plates 233, 235, 237, 239 can be used to heat a partially cured adhesive in receptacles of the frame portions 203, 205, 207, 209. In an embodiment, the partially cured adhesive can be heated to form a cured adhesive and to bond the laminate 220 to the frame (e.g., the frame including the frame portions 203, 205, 207, 209 collectively). In one embodiment, the pressing 232 and the heating can be performed in a single step. In some embodiments, the pressing can be performed to form a rectangular, or square, shape of the solar module as shown in FIG. 6.

FIG. 7 illustrates a solar module formed from the method of FIGS. 1-6, according to some embodiments. In an embodiment, the solar module 242 can have a laminate 220, solar cells 224 and a frame 240. The solar cells 224 can be connected and combined in the laminate 220, where the electrical energy from the solar cells 224 can be collected to provide power to an external circuit.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method for manufacturing a solar module, the method comprising:
placing a first edge of a laminate in a receptacle of a first frame portion, wherein the first edge of the laminate contacts a partially cured adhesive formed in the receptacle; and
curing the partially cured adhesive to form a cured adhesive to bond the laminate to the first frame portion.

2. The method of claim 1, further comprising:
placing a second edge of the laminate in a receptacle of a second frame portion, wherein the second edge of the laminate contacts a partially cured adhesive formed in the receptacle of the second frame portion.

3. The method of claim 2, further comprising:
placing third and fourth edges of the laminate in receptacles of third and fourth frame portions, respectively, wherein the third and fourth edges of the laminate contact a partially cured adhesive formed in the receptacles of third and fourth frame portions, respectively; and
wherein heating the partially cured adhesive forms the cured adhesive to bond the laminate to a frame comprising the first, second, third and fourth frame portions.

4. The method of claim 1, further comprising, before placing the first edge of the laminate in the receptacle of the first frame portion:
forming an adhesive in the receptacle of the first frame portion; and
partially curing the adhesive to form the partially cured adhesive.

5. The method of claim 5, wherein forming a partially cured adhesive comprises forming at least one of an epoxy or a B-stage epoxy.

6. The method of claim 1, wherein curing the partially cured adhesive comprises heating the partially cured adhesive.

7. The method of claim 1, wherein curing the partially cured adhesive comprises heating the partially cured adhesive with a heat plate.

8. A method for manufacturing a solar module, the method comprising:
placing a first edge of a laminate in a receptacle of a first frame portion having a partially cured adhesive, wherein the receptacle has three sides and the partially cured adhesive is formed on the three sides of the receptacle;
pressing a side of the first frame portion to contact at least one side of the receptacle to the first edge of the laminate; and
heating the partially cured adhesive to form a cured adhesive to bond the laminate to the first frame portion.

9. The method of claim 8, further comprising:
placing a second edge of the laminate in a receptacle of a second frame portion having a partially cured adhesive, wherein the receptacle has three sides and the partially cured adhesive is formed on the three sides of the receptacle of the second frame portion; and
pressing a side of the second frame portion to contact at least one side of the receptacle of second frame portion to the second edge of the laminate.

10. The method of claim 9, further comprising:
placing a third and fourth edge of the laminate in a receptacle of a third and fourth frame portion having a partially cured adhesive, wherein the receptacle has three sides and the partially cured adhesive is formed on the three sides of the receptacles of the third and fourth frame portions;
pressing sides of the third and fourth frame portions to contact at least one side of the receptacles of third and fourth frame portion to the third and fourth edge of the laminate, respectively; and
wherein heating the partially cured adhesive forms the cured adhesive to bond the laminate to a frame comprising the first, second, third and fourth frame portions.

11. The method of claim 10, wherein pressing sides of the first, second, third and fourth frame portions and heating the partially cured adhesive to form a cured adhesive to bond the laminate to a frame are performed in a single process.

12. The method of claim 8, further comprising, before placing the first edge of the laminate in the receptacle of the first frame portion:
forming an adhesive to the receptacle of the first frame portion; and
partially curing the adhesive to form a partially cured adhesive on three sides of the receptacle.

13. The method of claim 12, wherein forming a partially cured adhesive comprises forming at least one of an epoxy or a B-stage epoxy.

14. The method of claim 8, wherein heating the partially cured adhesive comprises heating the partially cured adhesive with a heat plate.

15. The method of claim 14, wherein pressing and heating is performed using the heat plate to align and bond the laminate to the first frame portion.

16. The method of claim 8, wherein pressing and heating is performed in a single process to align and bond the laminate to the first frame portion.

17. A solar module comprising:
a laminate having a first edge; and
a receptacle of a first frame portion connected to the first edge of the laminate, the receptacle comprising three sides and having an adhesive on the three sides, the adhesive bonding the laminate to the first frame portion.

18. The solar module of claim 17, further comprising:
the laminate having a second edge; and
a receptacle of a second frame portion connected to the second edge of the laminate, the receptacle comprising three sides and having an adhesive on the three sides, the adhesive bonding the laminate to the second frame portion.

19. The solar module of claim 18, further comprising:
the laminate having third and fourth edges; and
receptacles of third and fourth frame portions connected to the third and fourth edge of the laminate, respectively, the receptacles of the third and fourth frame portions each comprising three sides and having an adhesive on the three sides, the adhesive bonding the laminate to a frame, wherein the frame comprises the first, second, third and fourth frame portions.

20. The solar cell module of claim 16, wherein the adhesive is an epoxy, B-stage epoxy or a silicone sealant.
